(19) United States
(12) Patent Application Publication
(10) Pub. No.: US 2018/0175284 A1
(43) Pub. Date: Jun. 21, 2018

(54) INTEGRATED CIRCUITS AND METHODS FOR FABRICATING INTEGRATED CIRCUITS WITH MAGNETIC TUNNEL JUNCTION (MTJ) STRUCTURES

(71) Applicant: Globalfoundries Singapore Pte. Ltd., Singapore (SG)

(72) Inventors: Curtis Chun-I Hsieh, Singapore (SG); Wei-Hui Hsu, Singapore (SG); Wanbing Yi, Singapore (SG); Chim Seng Seet, Singapore (SG); Juan Boon Tan, Singapore (SG)

(21) Appl. No.: 15/383,122

(22) Filed: Dec. 19, 2016

(51) Int. Cl. H01L 43/02; H01L 43/12; H01L 43/08

(52) U.S. Cl. CPC H01L 43/02; H01L 43/08; H01L 43/12

(57) ABSTRACT

Integrated circuits and methods for fabricating integrated circuits with magnetic tunnel junction (MTJ) structures are provided. An exemplary method for fabricating an integrated circuit includes forming an MTJ structure including a top electrode layer. The MTJ structure has a first sidewall and a second sidewall separated from the first sidewall by a first width. The method includes forming a conductive etch stop on the top electrode layer. The conductive etch stop has a second width greater than the first width. The method also includes depositing dielectric material over the conductive etch stop and the MTJ structure. The method further includes etching the dielectric material to form a trench exposing the conductive etch stop. Also, the method includes forming a conductive via in the trench over and in electrical communication with the conductive etch stop.

### TECHNICAL FIELD

The technical field generally relates to integrated circuits, and more particularly relates to integrated circuits with magnetic tunnel junction structures.

### BACKGROUND

Magnetic (or magneto-resistive) random access memory (MRAM) is a non-volatile random access memory technology that could potentially replace the dynamic random access memory (DRAM) and flash memory as the standard memory for computing devices. The use of MRAM as a non-volatile RAM will eventually allow for “instant on” systems that come to life as soon as the system is turned on, thus saving the amount of time needed for a conventional PC, for example, to transfer boot data from a hard disk drive to volatile DRAM during system power up.

A magnetic memory element (also referred to as a tunneling magneto-resistive or TMR device) includes a structure having ferromagnetic layers separated by a non-magnetic layer (barrier), and arranged into a stacked magnetic tunnel junction (MTJ) structure. Digital information is stored and represented in the memory element as directions of magnetization vectors in the magnetic layers. More specifically, the magnetic moment of one magnetic layer (also referred to as a reference layer) is fixed or pinned, while the magnetic moment of the other magnetic layer (also referred to as a “free” layer) may be switched between the same direction and the opposite direction with respect to the fixed magnetization direction of the reference layer. The orientations of the magnetic moment of the free layer are also known as “parallel” and “antiparallel” states, wherein a parallel state refers to the same magnetic alignment of the free and reference layers, while an antiparallel state refers to opposing magnetic alignments therebetween.

The stacked MTJ structure is typically interconnected between a bottom electrode and a top electrode. MRAM devices, like semiconductor devices in general, are continually becoming smaller in size and require manufacturing processes that are capable of producing these devices. Alignment techniques are implemented during manufacturing processes in order to ensure correct alignment of the various layers and electrical connections within semiconductor devices.

In the context of MRAM devices, the MTJ stacks require proper electrical connection to the bottom electrode and top electrode. As device size is reduced, proper electrical connection for MTJ stacks is increasingly difficult to ensure within normal process flow parameters.

Accordingly, it is desirable to provide integrated circuits with magnetic tunnel junction (MTJ) structures. It is also desirable to provide MTJ structures with improved electrical connections. Further, it is desirable to provide methods for fabricating integrated circuits with MTJ structures that avoid improper electrical connections or shorting through misalignment or non-matched critical dimensions. Further, it is desirable to provide a method for fabricating an integrated circuit with MTJ structures that is cost effective and time efficient. Furthermore, other desirable features and characteristics will become apparent from the subsequent detailed description and the appended claims, taken in conjunction with the accompanying drawings and this background.

### BRIEF SUMMARY

Integrated circuits and methods for fabricating integrated circuits with magnetic tunnel junction (MTJ) structures are provided. In an exemplary embodiment, a method for fabricating an integrated circuit includes forming an MTJ structure including a top electrode layer. The MTJ structure has a first sidewall and a second sidewall separated from the first sidewall by a first width. The method includes forming a conductive etch stop on the top electrode layer. The conductive etch stop has a second width greater than the first width. The method also includes depositing dielectric material over the conductive etch stop and the MTJ structure. The method further includes etching the dielectric material to form a trench exposing the conductive etch stop. Also, the method includes forming a conductive via in the trench over and in electrical communication with the conductive etch stop.

In another exemplary embodiment, a method for fabricating an integrated circuit includes forming a magnetic tunnel junction (MTJ) structure including a top electrode layer. The method further includes depositing spacer material over the top electrode layer and around the MTJ structure. Also, the method includes removing the spacer material from over the top electrode layer to expose a top surface of the top electrode layer. Further, the method includes forming a conductive layer on the top surface of the top electrode layer and forming a conductive via in contact with the conductive layer.

In yet another exemplary embodiment, an integrated circuit is provided. The integrated circuit includes a magnetic tunnel junction (MTJ) structure including a top electrode layer. The MTJ structure has a first sidewall and a second sidewall separated from the first sidewall by a first width. Also, the integrated circuit includes a conductive layer on the top electrode layer. The conductive layer has a second width greater than the first width. The integrated circuit further includes a conductive via in contact with the conductive layer.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

The various embodiments will hereinafter be described in conjunction with the following drawing figures, wherein like numerals denote like elements, and wherein:

FIGS. 1-13 illustrate cross sectional views of a portion of an integrated circuit including a magnetic tunnel junction (MTJ) structure and a method of forming the same with an electrical connection to the MTJ structure according to various embodiments herein;

FIG. 1 illustrates formation of an MTJ structure in accordance with an embodiment herein;

FIGS. 2-3 illustrate formation of a conductive layer over the MTJ structure of FIG. 1 in accordance with an embodiment herein;

FIGS. 4-5 illustrate formation of a conductive layer over the MTJ structure of FIG. 1 in accordance with another embodiment herein;

FIG. 6 illustrates formation of an MTJ structure in accordance with another embodiment herein;

FIGS. 7-8 illustrate formation of a conductive layer over the MTJ structure of FIG. 6 in accordance with an embodiment herein;

FIGS. 9-10 illustrate formation of a conductive layer over the MTJ structure of FIG. 6 in accordance with another embodiment herein; and

FIGS. 11, 12 and 13 illustrate formation of an electrical connection to the MTJ structure of FIG. 5 in accordance with various embodiments herein.

### DETAILED DESCRIPTION

The following detailed description is merely exemplary in nature and is not intended to limit the integrated circuits with magnetic tunnel junction structures or methods for fabricating integrated circuits with magnetic tunnel junction structures. Furthermore, there is no intention to be bound by any expressed or implied theory presented in the preceding technical field, background or brief summary, or in the following detailed description.

For the sake of brevity, conventional techniques related to conventional device fabrication may not be described in detail herein. Moreover, the various tasks and processes described herein may be incorporated into a more comprehensive procedure or process having additional functionality not described in detail herein. In particular, various techniques in semiconductor fabrication processes are well-known and so, in the interest of brevity, many conventional techniques will only be mentioned briefly herein or will be omitted entirely without providing the well-known process details. Further, it is noted that integrated circuits include a varying number of components and that single components shown in the illustrations may be representative of multiple components. As used herein, when a structure includes or is formed of a recited material, that material is present in the structure in an amount of at least 10 wt. % unless otherwise indicated.

The drawings are semi-diagrammatic and not to scale. Particularly, some of the dimensions are for the clarity of presentation and are shown exaggerated in the drawings. Similarly, although the views in the drawings for ease of description generally show similar orientations, this depiction in the drawings is arbitrary. Generally, the integrated circuit can be operated in any orientation. As used herein, it will be understood that when an element or layer is referred to as being “over” or “under” another element or layer, it may be directly on the other element or layer, or intervening elements or layers may be present. When an element or layer is referred to as being “on” another element or layer, it is directly on and in contact with the other element or layer. Further, spatially relative terms, such as “upper”, “over”, “lower”, “under” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as being “under” other elements or features would then be oriented “above” the other elements or features. Thus, the exemplary term “under” can encompass either an orientation of above or below. The device may be otherwise oriented (rotated 90 degrees or at other orientations) and the spatially relative descriptors used herein may likewise be interpreted accordingly.

In accordance with the various embodiments herein, integrated circuits including magnetic tunneling junction (MTJ) structures and methods for fabricating integrated circuits with MTJ structures are provided. Generally, the following embodiments relate to the formation of overlying electrical connections, such as metallization layers, to integrate MTJ structures into the integrated circuits. Specifically, the following embodiments facilitate formation of electrical connections to MTJ structures with expanded process parameters by avoiding improper electrical connections or shorting due to misalignment or differences in process critical dimensions.

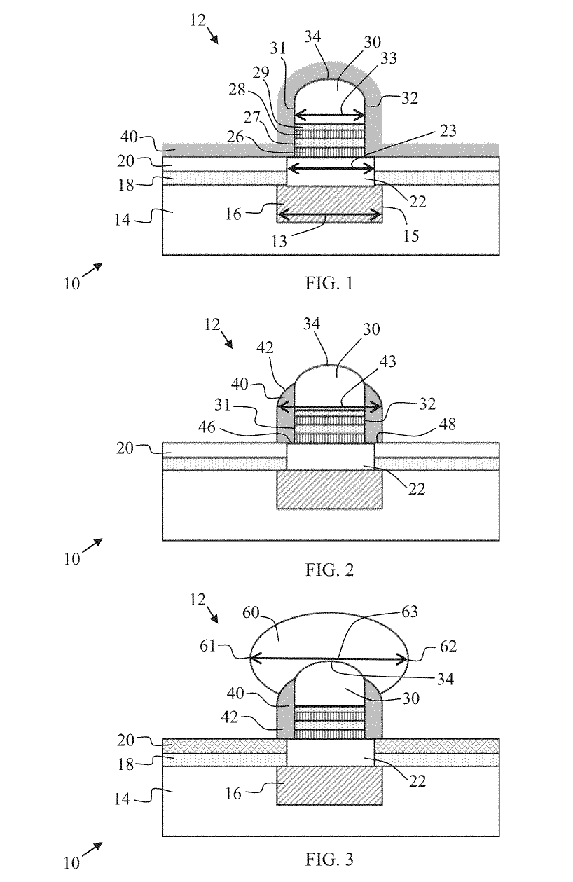

FIGS. 1-13 illustrate, in cross section, an integrated circuit 10 and methods for fabricating an integrated circuit 10 in accordance with embodiments of the present disclosure. Each of FIGS. 1-13 illustrates a memory portion of the integrated circuit 10, wherein a stacked MTJ structure 12 is to be formed. The integrated circuit 10 illustrated in FIG. 1 includes an inter-layer dielectric (ILD) layer 14 and a metallization layer 16 within the ILD layer 14. By the term “within,” it is meant that a top surface of the metallization layer 16 is substantially coplanar with a top surface of the ILD layer 14, and the metallization layer 16 extends downward into the ILD layer 14, as illustrated in FIG. 1. As shown, the metallization layer 16 has a maximum width 13 along the top surface. In an exemplary embodiment, the metallization layer 16 is formed with generally vertical and generally parallel sidewalls 15 such that the maximum width 13 of the metallization layer 16 is constant.

The ILD layer 14 may be formed of one or more low-k dielectric materials such as, for example, un-doped silicate glass (USG), silicon nitride, silicon oxynitride, or other commonly used materials. The dielectric constants (k value) of the low-k dielectric materials may be less than about 3.9, for example, less than about 2.8. The metallization layer 16 may be formed of a metal, such as copper or copper alloys. In one particular, non-limiting embodiment, the metallization layer 16 is a fourth metallization layer (M4) or fifth metallization layer (M5). One skilled in the art will realize the formation details of the ILD layer 14 and the metallization layer 16.

Though not illustrated for simplicity in FIGS. 1-13, the ILD layer 14 and the metallization layer 16 may be formed over other ILD and/or metallization layers, and also over an active region of a semiconductor substrate forming part of the integrated circuit structure. As used herein, the term “semiconductor substrate” may include any semiconductor materials typically used in the formation of electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. The substrate may further include a plurality of isolation features (not shown), such as shallow trench isolation (STI) features or local oxidation of silicon (LOCOS) features. The isolation features may define and isolate the various microelectronic elements (not shown), also referred to herein as the aforesaid active regions. Examples of the various microelectronic elements that may be formed in the substrate include transistors (e.g., metal oxide semiconductor field effect transistors (MOSFET): bipolar junction transistors (BJT); resistors; diodes; capacitors; inductors; fuses; or other suitable elements. Various processes are performed to form the various microelectronic elements including deposition, etching, implantation, photolithography, annealing, or other suitable processes. The microelectronic elements are interconnected to form the integrated circuit device, such as a logic device, memory device, radio frequency (RF) device, input/output (I/O) device, system-on-chip (SoC) device, combinations thereof, or other suitable types of devices.

As further illustrated in FIG. 1, a passivation layer 18 is formed over the top surface of the metallization layer 16 and the ILD layer 14. The passivation layer 18 may be formed of a non-organic material selected from un-doped silicate glass (USG), silicon nitride, silicon oxynitride, silicon oxide, or combinations thereof. In some alternative embodiments, the passivation layer 18 is formed of a polymer material, such as an epoxy, polyimide, benzocyclobutene (BCB), polybenzoxazole (PBO), or the like, although other relatively soft, often organic, dielectric materials may also be used.

In a specific, non-limiting embodiment, the passivation layer 18 may be formed of a silicon carbide-based passivation material including nitrogen. In one example, silicon carbide with nitrogen deposited using chemical vapor deposition (CVD) from a trimethylsilane source, which is commercially available from Applied Materials under the tradename of BLOK®, is used as the passivation layer 18. The compound with less nitrogen (N) (less than about 5 mol %), i.e., SiₐC_{b}N_{c}H_{d}, is referred to as “BLOK”, and the compound with more N (about 10 mol % to about 25 mol %), i.e., Si_{w}CₓN_{y}H_{z}, is referred to as “NBLOK”. BLOK has a lower dielectric constant of less than 4.0, whereas NBLOK has a dielectric constant of about 5.0. While BLOK is not a good oxygen barrier but is a good copper (Cu) barrier, NBLOK is both a good oxygen barrier and a good Cu barrier. In an exemplary embodiment, the passivation layer 18 includes NBLOK material.

In FIG. 1, a dielectric layer 20 is formed over the passivation layer 18. An exemplary dielectric layer 20 is silicon oxide, though other suitable dielectric materials may be used. In an exemplary embodiment, the dielectric layer 20 is formed by depositing a dielectric material using a chemical vapor deposition (CVD) process. Further, as shown, the passivation layer 18 and dielectric layer 20 are patterned to form an opening directly over the metallization layer 16. For example, a photoresist material layer (not shown) may be deposited over the dielectric layer 20 and patterned by exposure to a light source using known photolithographic processes. The patterning is performed so as to remove the photoresist material layer in an area directly over the metallization layer 16 and expose an upper surface of the dielectric layer 20 in the area that is directly over metallization layer 16. One or more etching steps are then performed to transfer the pattern into the dielectric layer 20 and passivation layer 18, forming a trench therein in the area that is directly over the metallization layer 16. As a result of the one or more etching steps, all or a portion of the upper surface of the metallization layer 16 is exposed. The remaining portions of the patterned photoresist layer are then removed (for example by a suitable polishing or planarization process), resulting substantially in the structure illustrated in FIG. 1, having the remaining portions (non-etched) of the upper surface of the dielectric layer 20 exposed, along with at least a portion of the upper surface of the metallization layer 16.

Further, bottom electrode layer 22 is formed on the upper surface of the metallization layer 16. An exemplary bottom electrode layer 22 is formed of a conductive material, such as a metal or a metal alloy. In an embodiment, bottom electrode layer 22 is formed of tantalum. In an exemplary embodiment, the conductive material is deposited by chemical vapor deposition (CVD) on to the metallization layer 16 and is planarized, such as by chemical mechanical planarization (CMP) to form a common planar upper surface 24 including the bottom electrode layer 22 and the dielectric layer 20. As shown, the bottom electrode layer 22 is formed with a maximum width 23. In an exemplary embodiment, the bottom electrode layer 22 is formed with parallel vertical sidewalls such that the maximum width 23 of the bottom electrode layer 22 is constant. In an exemplary embodiment, the maximum width 23 of the bottom electrode layer 22 is less than the maximum width 13 of the metallization layer 16.

The method may continue by forming MTJ layers 26, 27, 28 and 29 over the bottom electrode layer 22. For example, MTJ materials may be successively blanket deposited over the upper surface 24 of the bottom electrode layer 22 and dielectric layer 20. In an exemplary embodiment, MTJ layer 26 may be a pinning layer, MTJ layer 27 may be a fixed magnetic layer, MTJ layer 28 may be tunnel barrier layer, and MTJ layer 29 may be a free magnetic layer. An exemplary pinning layer 26 is formed of PtMn. An exemplary fixed magnetic layer 27 is formed of a CoFeB. An exemplary tunnel barrier layer 28 is formed of MgO. An exemplary free magnetic layer 29 is formed of CoFeB. The magnetic moment of free magnetic layer 29 may be programmed causing the resistance of the resulting MTJ structure 12 to be changed between a high resistance and a low resistance, in accordance with conventional techniques. It is realized that the MTJ structure 12 may include MTJ layers of many variations, such as including anti-ferro-magnetic layers (not shown), that are also within the scope of the present disclosure.

FIG. 1 further illustrates that the MTJ structure 12 includes a top electrode layer 30. Top electrode layer 30 is formed of a conductive material, such as a metal or a metal alloy. As used herein, the term “metal” broadly refers to the following elements:
Group 2 or IIA metals including beryllium (Be), magnesium (Mg), calcium (Ca), strontium (Sr), barium (Ba), and radium (Ra);
Groups 3-12 including transition metals (Groups MB, IVB, VB, VIB, VIIB, VIII, IB, and IIB), including scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os). cobalt (Co), rhodium (Rh), iridium (Ir), nickel (Ni), palladium (Pd), platinum (Pt), copper (Cu), silver (Ag), gold (Au), zinc (Zn), cadmium (Cd), and mercury (Hg);
Group 13 or IIIA including boron (B), aluminum (Al), gallium (Ga), indium (In), and thallium (TI): Lanthanides including lanthanum (La), cerium (Ce), praseodymium (Pr), neodymium (Nd), promethium (Pm), samarium (Sm), europium (Eu), gadolinium (Gd), terbium (Th), dysprosium (Dy), holmium (Ho), erbium (Er), thulium (Tm), ytterbium (Yb), and lutetium (Lu);
Group 14 or IVA including germanium (Ge), tin (Sn), and lead (Pb); and
Group 15 or VA including antimony (Sn) and bismuth (Bi).

In an exemplary embodiment, top electrode layer 30 is formed of tantalum, tantalum nitride, titanium, and/or other commonly used conductive metals. In an exemplary embodiment, the top electrode layer 30 is formed by depositing the conductive material by a CVD process.

As shown, MTJ layers 26-29 and top electrode layer 30 are etched to form the MTJ structure 12 with sidewalls 31 and 32. For example, a photoresist material layer (not shown) may be deposited and patterned over the top electrode layer 30, in the manner previously described with regard to the photoresist material layer used to etch the dielectric layer 20 and passivation layer 18, using a pattern that leaves a mask segment of photoresist material disposed over the area that is directly over the metallization layer 16. The photoresist segment serves as an etch mask for an etching process. The etching may be performed on the basis of a known technique, such as for example using tetrafluoromethane (CF₄) reactive ion etching (RIE) or hydrogen bromide (HBr). The bottom electrode layer 22 serves as an etch stop layer for the etching process. As a result of etching, all of the MTJ layers 26-29 and top electrode layer 30 are removed from over the dielectric layer 20 and from outer portions of the bottom electrode layer 22, except for an area directly underneath the photoresist material mask segment. Upon subsequent removal of the photoresist mask segment, the MTJ layers 26-29 and top electrode layer 30 form the MTJ structure 12 and have sidewalls 31 and 32. As shown, the MTJ structure 12 has a maximum width 33 extending from sidewall 31 to sidewall 32. In an exemplary embodiment, the sidewalls 31 and 32 are parallel such that the maximum width 33 of the MTJ structure 12 is constant. In an exemplary embodiment, the maximum width 33 of the MTJ structure 12 is less than the maximum width 23 of the bottom electrode layer 22 and less than the maximum width 13 of the metallization layer 16. As shown, the MTJ structure 12 has a top surface 34 formed by the top electrode layer 30.

In FIG. 1, a spacer/capping material 40 is deposited over and around the MTJ structure 12. For example, the spacer/capping material 40 is deposited on the dielectric layer 20 and on sidewalls 31 and 32 and top surface 34 of the MTJ structure 12. An exemplary spacer/capping material 40 is silicon nitride, though other suitable materials may be used. In an exemplary embodiment, the spacer/capping material 40 is deposited by low pressure chemical vapor deposition (LPCVD) or plasma-enhanced chemical vapor deposition (PECVD) processes.

The method may continue according to an embodiment in FIGS. 2-3 with removing the spacer/capping material 40 directly overlying the top surface 34 of the MTJ structure 12. As a result, spacers 42 are defined in FIG. 2 along the sidewalls 31 and 32 of the MTJ structure 12. In an exemplary embodiment, an anisotropic etching process, such as a reactive ion etching process, is used to etch the spacer/capping material 40 directly overlying the top surface 34 of the MTJ structure 12. Such a process also etches portions of the spacer/capping material 40 overlying the dielectric layer 20. As a result, spacers 42 are formed only along the sidewalls 31 and 32. The exemplary spacers 42 completely cover the previously exposed surface 46 of the bottom electrode layer 22 and cover adjacent surface portions 48 of the dielectric layer 20. As a result, the bottom electrode layer 22 is encapsulated by the overlying MTJ layer 26, spacers 42, and dielectric layer 20. In other words, the outer surfaces of the spacers 42 are separated from one another by a maximum distance 43. In an exemplary embodiment, the outer surfaces of the spacers 42 are generally parallel such that the maximum distance 43 between the outer surfaces is generally constant. In an exemplary embodiment, the maximum distance 43 is greater than the maximum width 23 (identified in FIG. 1) of the bottom electrode layer 22.

In FIG. 3, an additional conductive layer 60 is formed over the MTJ structure 12. As described below, the additional conductive layer 60 may perform as a landing material for an etching process and may be considered to be an etch stop 60. In an exemplary embodiment, the conductive layer 60 is formed by selective deposition on the top surface 34 of the top electrode layer 30. For example, a CVD process may be used to selectively deposit a conductive material forming the conductive layer 60 on the top surface 34 of the top electrode layer 30. An exemplary conductive layer 60 is metal, such as tungsten, cobalt, or ruthenium or a metal nitride such as tantalum nitride.

As shown, the exemplary deposition is isotropic such that the conductive layer 60 is formed with a side edge 61, a side edge 62, and a maximum width 63 from side edge 61 to side edge 62. In an exemplary embodiment, the maximum width 63 of the conductive layer 60 is greater than the maximum distance 43 (identified in FIG. 2) of spacers 42, greater than the maximum width 33 (identified in FIG. 1) of the MTJ structure 12, greater than the maximum width 23 (identified in FIG. 1) of the bottom electrode layer 22, and greater than the maximum width 13 (identified in FIG. 1) of the metallization layer 16.

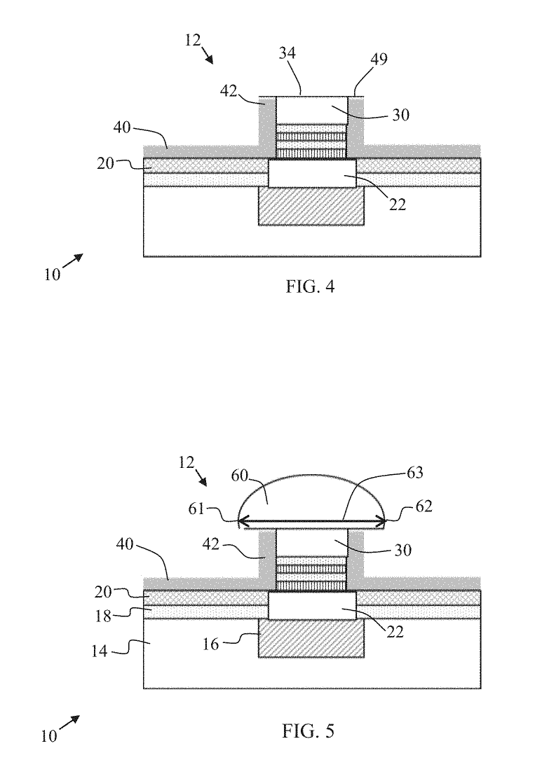

FIGS. 2-3 illustrate an embodiment for removing the spacer/capping material 40 directly overlying the top surface 34 of the MTJ structure 12 and for forming the conductive layer 60 over the top electrode layer 30 of the MTJ structure 12. FIGS. 4-5 illustrate an alternate embodiment for removing the spacer/capping material 40 directly overlying the top surface 34 of the MTJ structure 12 and for forming the conductive layer 60 over the top electrode layer 30 of the MTJ structure 12. In FIG. 4, the structure of FIG. 1 is planarized, such as by CMP. The planarization process removes the spacer/capping material 40 directly overlying the top surface 34 of the MTJ structure 12. Further, the planarization process planarizes the top surface 34 of the MTJ structure 12 and forms spacers 42 with a planar top surface 49. As shown, the spacer/capping material 40 remains on the dielectric layer 20 and encapsulates the bottom electrode layer 22. While not illustrated, the structure of FIG. 4 may include a dielectric layer adjacent the MTJ structure 12 and overlying the dielectric layer 20 that is also planarized during the removal of the spacer/capping material 40 directly overlying the top surface 34 of the MTJ structure 12.

The process continues in FIG. 5 as described with respect to FIG. 3. Specifically, the additional conductive layer/etch stop 60 is formed over the MTJ structure 12. As in the process of FIG. 3, the process of FIG. 5 forms the conductive layer 60 with side edge 61, side edge 62, and maximum width 63 that is greater than the maximum distance 43 (identified in FIG. 2) of spacers 42, greater than the maximum width 33 (identified in FIG. 1) of the MTJ structure 12, greater than the maximum width 23 (identified in FIG. 1) of the bottom electrode layer 22, and greater than the maximum width 13 (identified in FIG. 1) of the metallization layer 16.

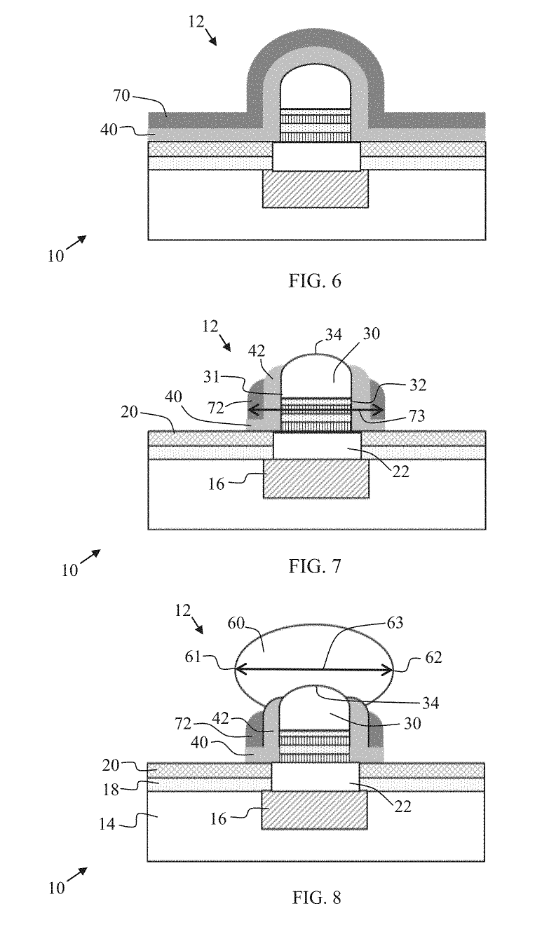

FIGS. 1-3 and FIGS. 1 and 4-5 illustrate two embodiments for forming a conductive layer 60 over a MTJ structure 12. FIGS. 6-8 and FIGS. 6 and 9-10 illustrate additional embodiments for forming a conductive layer 60 over a MTJ structure 12. In FIG. 6, the structure of the partially fabricated integrated circuit 10 is shown. Further to the process described in relation to FIG. 1 above, FIG. 6 illustrates the deposition of an optional liner material 70. In an exemplary embodiment, the liner material 70 is conformally deposited, such as by a PECVD process. An exemplary liner material 70 is silicon oxide, though other suitable materials may be used. In an exemplary embodiment, the liner material 70 is different from the spacer/capping material 40 such that etchant selectivity may be optimized during the later removal of portions of the liner material 70 and spacer/capping material 40.

The process may continue in FIG. 7 with removing the liner material 70 and the spacer/capping material 40 directly overlying the top surface 34 of the MTJ structure 12. For example, the liner material 70 may be etched using an anisotropic etching process, such as reactive ion etching, selective to etching the liner material 70. The process also etches portions of the liner material 70 overlying the dielectric layer 20 laterally adjacent the MTJ structure 12. As a result, liners 72 may be formed around the sidewalls 31 and 32 of the MTJ structure 12. As shown, the liners 72 are spaced from the sidewalls 31 and 32 by the intervening spacer/capping material 40. The outer surfaces of the liners 72 are separated from one another by a maximum distance 73. In an exemplary embodiment, the outer surfaces of the liners 72 are parallel such that the maximum distance 73 between the outer surfaces is constant.

In FIG. 7, the spacer/capping material 40 directly overlying the top surface 34 of the MTJ structure 12 is removed similarly to the process described in relation to FIG. 2 to define spacers 42 along the sidewalls 31 and 32 of the MTJ structure 12.

In an exemplary embodiment, the maximum distance 73 between the outer surfaces of the liners 72 is greater than the maximum width 13 (identified in FIG. 1) of the metallization layer 16, greater than the maximum width 23 (identified in FIG. 1) of the bottom electrode layer 22, and greater than the maximum distance 43 (identified in FIG. 2) of the spacers 42.

The process may continue in FIG. 8 with the formation of the conductive layer 60 over the top electrode layer 30 as described above in relation to FIG. 3. As a result, the structure of the partially fabricated integrated circuit 10 of FIG. 8 is substantially identical to that of the partially fabricated integrated circuit 10 of FIG. 3, with the addition of the liners 72 around the spacers 42.

As shown, the exemplary deposition of conductive material forming conductive layer 60 is isotropic such that the conductive layer 60 is formed with a side edge 61, a side edge 62, and a maximum width 63 from side edge 61 to side edge 63. In an exemplary embodiment, the maximum width 63 of the conductive layer 60 is greater than the maximum distance 73 of liners 72, greater than the maximum distance 43 (identified in FIG. 2) of spacers 42, greater than the maximum width 33 (identified in FIG. 1) of the MTJ structure 12, greater than the maximum width (identified in FIG. 1) of the bottom electrode layer 22, and greater than the maximum width 13 (identified in FIG. 1) of the metallization layer 16.

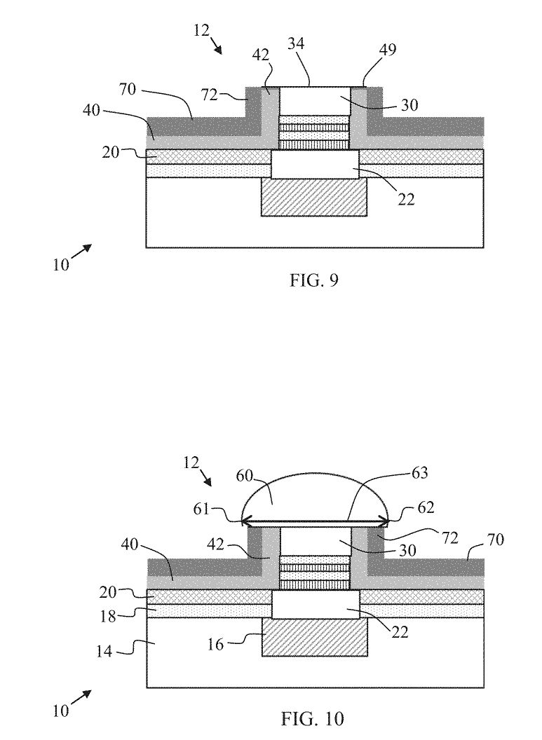

FIGS. 7-8 illustrate an embodiment for removing the liner material 70 and spacer/capping material 40 directly overlying the top surface 34 of the MTJ structure 12 and for forming the conductive layer 60 over the top electrode layer 30 of the MTJ structure 12. FIGS. 9-10 illustrate an alternate embodiment for removing the liner material 70 and spacer/capping material 40 directly overlying the top surface 34 of the MTJ structure 12 and for forming the conductive layer 60 over the top electrode layer 30 of the MTJ structure 12. In FIG. 9, the structure of FIG. 6 is planarized, such as by CMP. The planarization process removes the liner material 70 and the spacer/capping material 40 directly overlying the top surface 34 of the MTJ structure 12. Further, the planarization process planarizes the top surface 34 of the MTJ structure 12 and forms liners 72 and spacers 42 with a planar top surface 49. As shown, the liner material 70 and spacer/capping material 40 remain on the dielectric layer 20 and encapsulate the bottom electrode layer 22. While not illustrated, the structure of FIG. 9 may include a dielectric layer adjacent the MTJ structure 12 and overlying the dielectric layer 20 that is also planarized during the removal of the liner material 70 and spacer/capping material 40 directly overlying the top surface 34 of the MTJ structure 12.

The process continues in FIG. 10 as described with respect to FIG. 8. Specifically, the additional conductive layer/etch stop 60 is formed over the MTJ structure 12. As in the process of FIG. 8, the process of FIG. 10 forms the conductive layer 60 with side edge 61, side edge 62, and maximum width 63 that is greater than the maximum distance 73 of liners 72, greater than the maximum distance 43 (identified in FIG. 2) of spacers 42, greater than the maximum width 33 (identified in FIG. 1) of the MTJ structure 12, greater than the maximum width 23 (identified in FIG. 1) of the bottom electrode layer 22, and greater than the maximum width 13 (identified in FIG. 1) of the metallization layer 16.

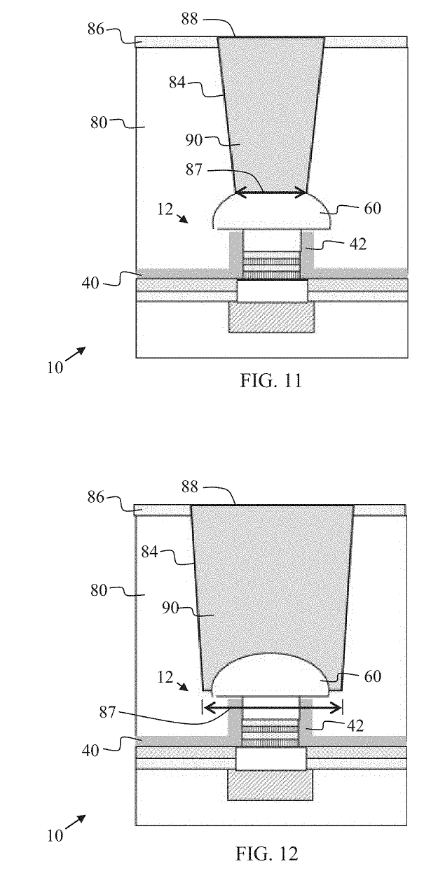

FIGS. 1-10 illustrate various embodiments for forming the conductive layer 60 over the top electrode layer 30 of the MTJ structure 12. FIGS. 11, 12 and 13 illustrate embodiments for forming electrical connections to the conductive layer 60. The structure of the partially fabricated integrated circuit 10 of FIG. 5 is shown in FIGS. 11, 12 and 13, though the structures of the integrated circuit 10 of FIG. 3, 8 or 10 may alternatively be used.

In FIGS. 11, 12 and 13, the method may continue with the deposition of dielectric material 80. Dielectric material 80 may be formed from a plurality of dielectric layers, including an interlayer dielectric, such as a low k interlayer dielectric. Further, dielectric material 80 may include dielectric layers formed during previous processing, such as before the CMP process of FIG. 4 or 9. In FIGS. 11, 12 and 13, dielectric material 80 may be blanket deposited over the conductive layer 60, spacers 42 and spacer/capping material 40. The dielectric material 80 may be blanket deposited over the conductive layer 60, spacers 42 and dielectric layer 20 (for the structure of FIG. 3), over the conductive layer 60, liners 72, spacers 42, and dielectric layer 20 (for the structure of FIG. 8), or over the conductive layer 60, liners 72 and liner material 70 (for the structure of FIG. 10). As shown, the dielectric material 80 is planarized, such as by CMP.

Trenches 84 are then formed in the dielectric material 80 for the purposes of forming electrically connecting the conductive layer 60 to other components in the integrated circuit 10 through additional metallization layers (not shown). For example, a mask 86 may be located and pattered over the dielectric material 80 to form an opening 88 overlying the MTJ structure 12. Then, an etch process is performed to etch the dielectric material 80 directly underlying the opening 88. An exemplary etch process is anisotropic, such as a reactive ion etch. The exemplary etch process is selective to etching the dielectric material 80 and does not etch, or etches very slowly, the conductive layer 60. As a result, each trench 84 is intended to land on the conductive layer 60.

Conductive material is then deposited over the dielectric material 80, in the trenches 84, and on the conductive layer 60. An overburden portion of the conductive material may be removed from over the mask 86. As a result, conductive vias 90 are formed in the trenches 84 and in electrical contact with the conductive layer 60. Exemplary conductive vias 90 are formed from conductive material of any type commonly used in the fabrication of via structures, including but not limited to copper-containing materials. In an exemplary embodiment, the conductive material is deposited by an electroplating process.

FIGS. 11, 12 and 13 illustrate different structures resulting from the trench etch and via formation process. In FIG. 11, the trench 84 is properly aligned with and centered on the conductive layer 60. Further, the trench 84 in FIG. 11 has a bottom width 87 that is less than the maximum width 63 (identified in FIGS. 3, 5, 8 and 10) of the conductive layer 60. Such a structure may result when the critical dimension of the trench formation process is less than the maximum width 63 of the conductive layer 60.

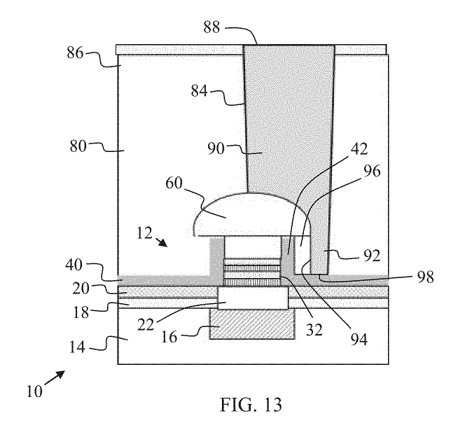

In FIG. 12, the trench 84 is properly aligned with and centered on the conductive layer 60. However, the trench 84 in FIG. 11 has a bottom width 87 that is greater than the maximum width 63 (identified in FIGS. 3, 5, 8 and 10) of the conductive layer 60. Such a structure may result when the critical dimension of the trench formation process is greater than the maximum width 63 of the conductive layer 60. Using a timed etch process may allow the etch process to be stopped before the trench 84 extends deeper than the conductive layer 60. However, even if the etch process causes the trench 84 to land on the spacer/capping material 40 (or liner material 70 or dielectric layer 20), improper connect or shorting from the MTJ structure, 12, the bottom electrode layer 22 or the metallization layer 16 to the conductive via 90 is avoided as described with respect to FIG. 13.

In FIG. 13, the trench 84 is not aligned with and centered on the conductive layer 60 despite the critical dimension of the trench etch process being less than the maximum width 63 (identified in FIGS. 3, 5, 8 and 10) of the conductive layer 60. As shown, trench 84 and a portion 92 of the conductive via 90 extend below the conductive layer 60 to the spacer/capping material 40 laterally adjacent the MTJ structure 12. Due to the structure of the integrated circuit 10, the inner surface 94 of the portion 92 of the conductive via 90 is separated from the sidewall 32 of the MTJ structure 12 by a portion 96 of the dielectric material 80 directly under the conductive layer 60 and by spacer 42. Further, the bottom end 98 of the portion 92 of the conductive via 90 is separated from the bottom electrode layer 22 in the lateral direction by the thickness of the portion 96 of the dielectric material 80 directly under the conductive layer 60 and in the vertical direction by the spacer/capping material 40. Also, the bottom end 98 of the portion 92 of the conductive via 90 is separated from the metallization layer 16 in the lateral direction by the thickness of the portion 96 of the dielectric material 80 directly under the conductive layer 60 and in the vertical direction by the spacer/capping material 40, the dielectric layer 20 and the passivation layer 18.

As can be seen in FIG. 13, the conductive layer 60 acts as an umbrella or shield to block the anisotropic trench etch process from landing on the conductive elements of the MTJ structure 12, the bottom electrode layer 22 or the metallization layer 16, or close enough to the conductive elements of the MTJ structure 12, the bottom electrode layer 22 or the metallization layer 16 to allow shorting from a conductive via formed in the trench to those conductive elements. Thus, even for the embodiment of FIG. 12, in which a trench etch has a critical dimension greater than the maximum width 63 of the conductive layer 60, improper electrical connection or shorting between the conductive via 90 and the MTJ structure 12, the bottom electrode layer 22 or the metallization layer 16 is avoided.

As described herein, integrated circuits with magnetic tunnel junction structures and methods for fabricating integrated circuits with magnetic tunnel junction structures are provided. The integrated circuits and methods described herein avoid improper electrical connection from electrical connection structures to MTJ structures through use of additional conductive material formed over the MTJ structures. As described, the exemplary integrated circuits and methods achieve improved processing flexibility by expanding etching process parameters and providing leeway for improper alignment or mismatched critical dimensions.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration as claimed in any way. Rather, the foregoing detailed description will provide those skilled in the art with a convenient road map for implementing the exemplary embodiment or exemplary embodiments. It should be understood that various changes can be made in the function and arrangement of elements without departing from the scope herein as set forth in the appended claims and the legal equivalents thereof.

1. A method for fabricating an integrated circuit, the method comprising:
forming a magnetic tunnel junction (MTJ) structure including a top electrode layer, wherein the MTJ structure has a first sidewall and a second sidewall separated from the first sidewall by a first width;
selectively depositing a conductive etch stop on the top electrode layer, wherein the conductive etch stop has a second width greater than the first width;
depositing dielectric material over the conductive etch stop and the MTJ structure;
etching the dielectric material to form a trench exposing the conductive etch stop; and
forming a conductive via in the trench over and in electrical communication with the conductive etch stop.

2. The method of claim 1 further comprising forming spacers along the first and second sidewalls of the MTJ structure, wherein selectively depositing the conductive etch stop comprises forming the conductive etch stop over the spacer.

3. The method of claim 2 wherein forming the spacer along the first and second sidewalls of the MTJ structure comprises:
depositing spacer material over the top electrode layer and along the first and second sidewalls of the MTJ structure; and
removing the spacer material from over the top electrode layer.

4. The method of claim 3 wherein removing the spacer material from over the top electrode layer comprises etching the spacer material over the top electrode layer.

5. The method of claim 3 wherein removing the spacer material from over the top electrode layer comprises planarizing the spacer material over the top electrode layer.

6. The method of claim 3 further comprising forming a liner over the spacer material, wherein removing the spacer material from over the top electrode layer comprises removing the liner from over the top electrode layer.

7. The method of claim 6 wherein:
forming the spacer along the sidewalls of the MTJ structure comprises depositing silicon nitride over the MTJ structure; and
forming the liner over the spacer material comprises depositing silicon oxide over the silicon nitride.

8. The method of claim 1 wherein selectively depositing the conductive etch stop on the top electrode layer comprises selectively depositing metal on the top electrode layer.

9. The method of claim 1 wherein selectively depositing the conductive etch stop on the top electrode layer comprises selectively depositing tungsten, cobalt, tantalum nitride or ruthenium on the top electrode layer.

10. (canceled)

11. A method for fabricating an integrated circuit, the method comprising:
forming a magnetic tunnel junction (MTJ) structure including a top electrode layer;
depositing a spacer material over and beside the MTJ structure;
removing the spacer material from over the top electrode layer to expose a top surface of the top electrode layer;
performing an isotropic deposition process to form a conductive layer on the top surface of the top electrode layer; and
forming a conductive via in contact with the conductive layer.

12. The method of claim 11 wherein:
depositing the spacer material over the top electrode layer and around the MTJ structure and removing the spacer material from over the top electrode layer comprises forming a spacer around the MTJ structure; and
performing the isotropic deposition process to form the conductive layer on the top surface of the top electrode layer comprises forming the conductive layer directly over the spacer.

13. The method of claim 11 wherein:
the method further comprises depositing an interlayer dielectric around the spacer material after performing the isotropic deposition process to form the conductive layer;
depositing the spacer material over the top electrode layer and around the MTJ structure and removing the spacer material from over the top electrode layer comprises forming a spacer around the MTJ structure; and
performing the isotropic deposition process to form the conductive layer on the top surface of the top electrode layer comprises forming the conductive layer directly over the spacer and directly over a portion of the interlayer dielectric.

14. The method of claim 11 further comprising:
depositing a liner material over the spacer material; and
removing the liner material from over the top electrode layer.

15. The method of claim 11 wherein performing the isotropic deposition process to form the conductive layer on the top surface of the top electrode layer comprises selectively depositing metal on the top electrode layer.

16. The method of claim 11 wherein performing the isotropic deposition process to form the conductive layer on the top surface of the top electrode layer comprises selectively depositing tungsten, cobalt, tantalum nitride or ruthenium on the top electrode layer.

17. The method of claim 11 further comprising:
depositing dielectric material over the conductive layer and the MTJ structure; and
etching the dielectric material to form a trench landing on the conductive layer, wherein forming the conductive via in contact with the conductive layer comprises forming the conductive via in the trench.

18-20. (canceled)

21. The method of claim 1 wherein depositing the dielectric material over the conductive etch stop and the MTJ structure comprises depositing the dielectric material beside the MTJ structure after selectively depositing the conductive etch stop on the top electrode layer.

22. The method of claim 1 wherein depositing the dielectric material over the conductive etch stop and the MTJ structure comprises depositing the dielectric over the conductive etch stop without first etching the conductive etch stop.

23. A method for fabricating an integrated circuit, the method comprising:
forming a magnetic tunnel junction (MTJ) structure including a top electrode layer and sidewalls;
performing an isotropic deposition process to deposit a conductive material on the top electrode layer, wherein the conductive material grows outward from the sidewalls of the MTJ structure to opposite side edges during the isotropic deposition process, and wherein a conductive etch stop is defined by the conductive material between the side edges; and
forming a conductive via in contact with the conductive etch stop.

24. The method of claim 23 further comprising:
depositing dielectric material over the conductive etch stop and the MTJ structure before the conductive etch stop is etched; and
etching the dielectric material to form a trench exposing and partially etching the conductive etch stop, wherein forming the conductive via in contact with the conductive etch stop comprises forming the conductive via in the trench.
